(19) United States
(12) Patent Application Publication
(10) Pub. No.: US 2026/0255705 A1
(43) Pub. Date: Aug. 27, 2026

(54) SEMICONDUCTOR DEVICE AND METHOD FOR MANUFACTURING THE SAME

(71) Applicant: SONY SEMICONDUCTOR SOLUTIONS CORPORATION, KANAGAWA (JP)

(72) Inventor: Tsukasa MIURA, KANAGAWA (JP)

(21) Appl. No.: 18/995,177

(22) PCT Filed: Jul. 7, 2023
(86) PCT No.: PCT/JP2023/025222

§ 371 Date: Jan. 16, 2025

(30) Foreign Application Priority Data
Jul. 26, 2022 (JP) 2022-119071

(51) Int. Cl. H10F 39/00; H10W 80/00; H10W 90/00; H10W 90/20

(52) U.S. Cl. CPC H10F 39/803; H10F 39/809; H10W 80/327; H10W 90/293; H10W 90/792

(57) ABSTRACT

A semiconductor device (100) includes: a first substrate (2) including a first electrode (6); a second substrate (3) including a second electrode (8) disposed to face the first electrode; and an oxide layer (7) of at least one of the first electrode or the second electrode, the oxide layer (7) being disposed between the first electrode and the second electrode. The semiconductor device (100) can increase the capacitance of a capacitor, without hindering miniaturization.

### TECHNICAL FIELD

The present disclosure relates to a semiconductor device and a method for manufacturing the semiconductor device.

### BACKGROUND ART

An imaging device such as an image sensor tends to have a higher resolution than before, and there is a demand for reducing the pixel size without a decrease in sensitivity.

To achieve miniaturization, an imaging device in which a plurality of chips is stacked has been put into practical use (see Patent Document 1, for example). The imaging device disclosed in Patent Document 1 adopts a pixel analog-digital converter (ADC) system that performs analog-digital conversion on a pixel signal in a pixel. By the pixel ADC system, all the pixels perform analog-digital conversion at the same timing. Thus, it is possible to eliminate distortion of a captured image when a moving subject is imaged.

### CITATION LIST

### Patent Document

Patent document 1: Japanese Patent Application Laid-Open No. 2021-176206

### SUMMARY OF THE INVENTION

### Problems to be Solved by the Invention

Since an imaging device of the pixel ADC system is easily affected by random noise, it is necessary to take measures to increase the capacitance of the capacitor provided in each pixel, to reduce the influence of random noise.

In the imaging device of the pixel ADC system, however, it is necessary to provide a comparator or the like necessary for AD conversion in each pixel, and it is not easy to increase the capacitance of the capacitor.

Even in an imaging device of a column ADC system different from the pixel ADC system, miniaturization of pixels has advanced, and it is difficult to secure a space for increasing the capacitance of the capacitor in each pixel.

Therefore, the present disclosure provides a semiconductor device capable of increasing the capacitance of a capacitor without hindering miniaturization, and a method for manufacturing the semiconductor device.

### Solutions to Problems

To solve the above problems, the present disclosure provides a semiconductor device that includes:
a first substrate including a first electrode;
a second substrate including a second electrode disposed to face the first electrode; and
an oxide layer of at least one of the first electrode or the second electrode, the oxide layer being disposed between the first electrode and the second electrode.

A capacitor may include the first electrode, the oxide layer, and the second electrode.

The semiconductor device may further include an insulating film that is disposed at least between the first electrode and the oxide layer or between the second electrode and the oxide layer, and is thinner than the oxide layer.

The insulating film may contain an oxide, a nitride, or a metal oxide.

The oxide layer may include:
a first oxide layer formed by oxidizing a surface of the first electrode; and
a second oxide layer formed by oxidizing a surface of the second electrode, and
the capacitor may include the first electrode, the first oxide layer, the second oxide layer, and the second electrode.

The semiconductor device may further include a first insulating film and a second insulating film that are stacked between the first oxide layer and the second oxide layer, in which
the first insulating film and the second insulating film may be thinner than the first oxide layer and the second oxide layer.

The first insulating film and the second insulating film may contain an oxide, a nitride, or a metal oxide.

The semiconductor device may further include:
a first conductive layer that is disposed at the same layer height as the first electrode and at a distance from the first electrode; and
a second conductive layer that is disposed at the same height as the second electrode and at a distance from the second electrode, in which
the first conductive layer and the second conductive layer may be disposed to face each other and be joined to each other.

The first electrode, the second electrode, the first conductive layer, and the second conductive layer may contain the same metal material.

The first electrode and the second electrode may contain a first metal material, and
the first conductive layer and the second conductive layer may contain a second metal material different from the first metal material.

The first metal material may be a material that is less likely to cause thermal diffusion than the second metal material.

The oxide layer may have a thickness that is not smaller than 1 nm and not greater than 10 nm.

The insulating film may have a thickness that is not smaller than 0.1 nm and not greater than 1 nm.

Each of the first insulating film and the second insulating film may have a thickness that is not smaller than 0.1 nm and not greater than 1 nm.

The first substrate may include a plurality of pixels that perform photoelectric conversion,
the second substrate may include a signal processing circuit that performs signal processing on a pixel signal photoelectrically converted by the plurality of pixels, and
the pixels may include:
a photoelectric conversion element,
an analog-digital converter that compares an electric signal photoelectrically converted by the photoelectric conversion element with a reference signal, and outputs a signal indicating a comparison result, and
the capacitor.

The capacitor may be disposed within a region of a corresponding one of the pixels on a bonding surface between the first substrate and the second substrate.

The present disclosure provides a method for manufacturing a semiconductor device, the method including:
a step of forming a first conductive layer and a first electrode on a first substrate;
a step of forming a second conductive layer and a second electrode on a second substrate;
a step of forming an oxide layer by oxidizing a surface of at least one of the first electrode or the second electrode; and
a step of forming a capacitor including the first electrode, the oxide layer, and the second electrode by disposing the first conductive layer and the second conductive layer to face each other, bringing the first conductive layer and the second conductive layer into contact with each other, joining the first conductive layer and the second conductive layer, and disposing the first electrode and the second electrode to face each other.

The method may further include a step of forming an insulating film on a surface of at least one of the first substrate or the second substrate, on which the oxide layer is formed, the insulating film being thinner than the oxide layer.

The step of forming the oxide layer may include:
a step of forming a first oxide layer by oxidizing a surface of the first electrode; and
a step of forming a second oxide layer by oxidizing a surface of the second electrode;
the step of forming the insulating film may include:
a step of forming a first insulating film on a surface of the first oxide layer, the first insulating film being thinner than the first oxide layer; and
a step of forming a second insulating film on a surface of the second oxide layer, the second insulating film being thinner than the second oxide layer, and
the step of forming the capacitor may include bringing the first conductive layer and the second conductive layer into contact with each other, and disposing the first oxide layer and the second oxide layer between the first electrode and the second electrode, by performing heat treatment after bringing the first insulating film and the second insulating film into contact with each other while the first conductive layer and the second conductive layer are disposed to face each other, and the first electrode and the second electrode are disposed to face each other.

The first conductive layer and the first electrode may contain different metal materials from each other,
the second conductive layer and the second electrode may contain different metal materials from each other, and
the step of forming the capacitor may include: performing heat treatment to bring the metal materials of the first conductive layer and the second conductive layer into contact with each other; and performing heat treatment to bring the metal materials of the first electrode and the second electrode apart from each other.

### BRIEF DESCRIPTION OF DRAWINGS

FIG. 1 is a block diagram illustrating a schematic configuration of a semiconductor device 1 according to the present disclosure.

FIG. 2 is a block diagram illustrating the configuration of each of the pixels arranged in a two-dimensional array in a pixel array unit.

FIG. 3 is a circuit diagram illustrating the details of a pixel circuit 41 and a comparison circuit 51 illustrated in FIG. 2.

FIG. 4 is a diagram illustrating an example in which a pixel chip and a logic chip are stacked to form a solid-state imaging device.

FIG. 5A is a schematic plan view of the vicinity of a bonding surface between a pixel chip 2 and a logic chip 3.

FIG. 5B is a cross-sectional view taken along the line A-A defined in FIG. 5A.

FIG. 6A is a process cross-sectional view for explaining a process of manufacturing a second capacitor C2.

FIG. 6B is a process cross-sectional view subsequent to FIG. 6A.

FIG. 6C is a process cross-sectional view subsequent to FIG. 6B.

FIG. 7A is a process cross-sectional view subsequent to FIG. 6C.

FIG. 7B is a process cross-sectional view subsequent to FIG. 7A.

FIG. 8A is a process cross-sectional view subsequent to FIG. 7B.

FIG. 8B is a process cross-sectional view subsequent to FIG. 8A.

FIG. 8C is a process cross-sectional view subsequent to FIG. 8B.

FIG. 9A is a process cross-sectional view subsequent to FIG. 8C.

FIG. 9B is a process cross-sectional view subsequent to FIG. 9A.

FIG. 10A is a process cross-sectional view subsequent to FIG. 9B.

FIG. 10B is a process cross-sectional view subsequent to FIG. 10A.

FIG. 11 is a cross-sectional view illustrating an eventual cross-section structure of a semiconductor device according to a first modification.

FIG. 12 is a cross-sectional view of a semiconductor device according to a second modification in which the process of forming a first oxide layer is omitted.

FIG. 13 is a cross-sectional view of a semiconductor device according to the second modification in which the process of forming a second oxide layer is omitted.

FIG. 14 is a cross-sectional view of a semiconductor device 1 according to a third modification.

FIG. 15 is a block diagram illustrating a schematic configuration of an electronic device.

FIG. 16 is a block diagram illustrating an example of a schematic configuration of a vehicle control system.

FIG. 17 is an explanatory diagram illustrating an example of installation positions of an outside-vehicle information detecting section and imaging sections.

### MODE FOR CARRYING OUT THE INVENTION

The following is a description of embodiments of a semiconductor device and a method for manufacturing the semiconductor device, with reference to the drawings. Although principal components of the semiconductor device will be mainly described below, the semiconductor device may have components and functions that are not illustrated or described. The following description does not exclude components and functions that are not illustrated or described.

### Example of a Schematic Configuration of an Imaging Device

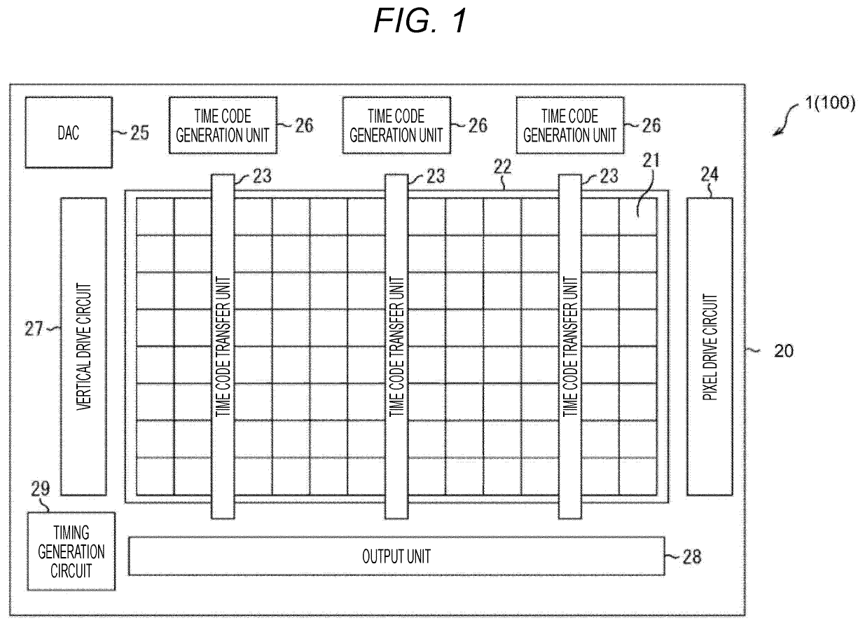

FIG. 1 is a block diagram illustrating a schematic configuration of a semiconductor device 1 according to the present disclosure. The semiconductor device 1 in FIG. 1 includes a solid-state imaging device 100.

A solid-state imaging device 100 in FIG. 1 includes a semiconductor substrate 20 formed with silicon (Si), for example, and a pixel array unit 22 in which pixels 21 are arranged in a two-dimensional array is provided on the semiconductor substrate 20. Time code transfer units 23 that transfer a time code generated by a time code generation unit 26 to the respective pixels 21 are provided in the pixel array unit 22. A pixel drive circuit 24, a D/A converter (DAC) 25, the time code generation unit 26, a vertical drive circuit 27, an output unit 28, and a timing generation circuit 29 are provided around the pixel array unit 22 on the semiconductor substrate 20.

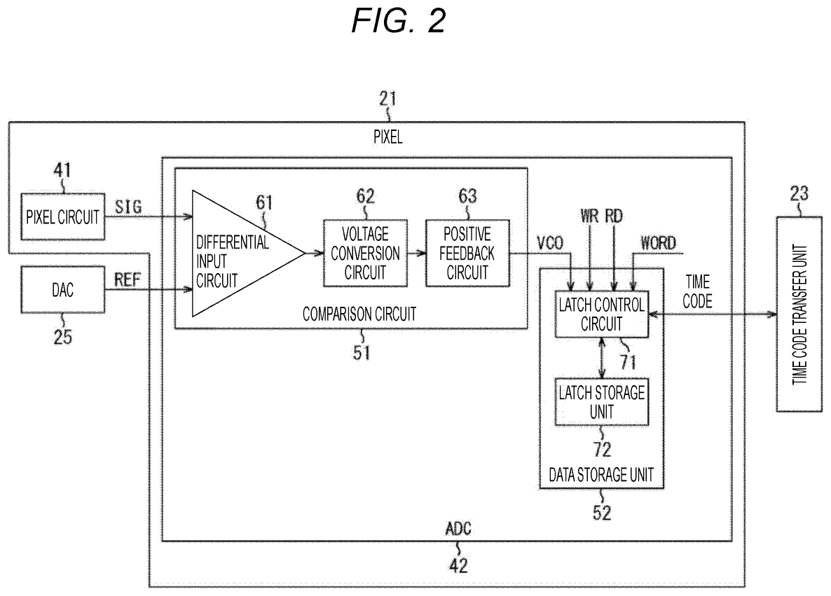

FIG. 2 is a block diagram illustrating the configuration of each of the pixels 21 arranged in a two-dimensional array in the pixel array unit 22. As illustrated in FIG. 2, each pixel 21 includes a pixel circuit 41 and an analog-digital converter (ADC) 42. Each pixel 21 generates a charge signal corresponding to the amount of light received by a light receiving element (a photodiode, for example) in the pixel, converts the charge signal into a digital pixel signal, and outputs the digital pixel signal. As described above, the solid-state imaging device 100 in FIG. 1 is a pixel-ADC imaging device including the ADC 42 for each pixel 21.

The pixel drive circuit 24 in FIG. 1 drives the pixel circuit 41 (FIG. 2) in the pixel 21. A DAC 25 generates a reference signal REF (reference voltage signal) REF, which is a slope signal whose level (voltage) monotonously decreases with the lapse of time, and supplies the reference signal REF to each pixel 21. The time code generation unit 26 generates a time code to be used when each pixel 21 converts an analog pixel signal SIG into a digital signal (AD conversion), and supplies the time code to the corresponding time code transfer unit 23. A plurality of the time code generation units 26 is provided for the pixel array unit 22, and, in the pixel array unit 22, the time code transfer units 23 are provided as many as the time code generation units 26. That is, the time code generation units 26 and the time code transfer units 23 that transfer the time codes generated in the time code generation units 26 are in one-to-one correspondence.

The vertical drive circuit 27 performs control to output digital pixel signals generated in the pixels 21 to the output unit 28 via the time code transfer units 23 in a predetermined order, on the basis of a timing signal supplied from the timing generation circuit 29. The digital pixel signals output from the pixels 21 are output from the output unit 28 to the outside of the solid-state imaging device 100. The output unit 28 performs predetermined digital signal processing such as a black level correction process for correcting black level and a correlated double sampling (CDS) process as necessary, and then outputs the resultant signals to the outside. As described above, the output unit 28 has a function of performing various kinds of arithmetic processing and signal processing.

The timing generation circuit 29 includes a timing generator that generates various timing signals and the like, and supplies the generated various timing signals to the pixel drive circuit 24, the DAC 25, the vertical drive circuit 27, and the like.

As will be described later, the solid-state imaging device 100 in FIG. 1 can be divided into a pixel chip 2 and a logic chip 3, and the pixel chip 2 and the logic chip 3 are stacked to perform bonding by Cu—Cu bonding and transmission of various signals.

### Specific Example of the Configuration of a Pixel

As described above, a pixel 21 includes a pixel circuit 41 and an ADC 42. As illustrated in FIG. 2, the pixel circuit 41 outputs a charge signal corresponding to the amount of received light to the ADC 42 as an analog pixel signal SIG. The ADC 42 converts the analog pixel signal SIG supplied from the pixel circuit 41 into a digital signal. The ADC 42 includes a comparison circuit 51 and a data storage unit 52.

The comparison circuit 51 compares the reference signal REF supplied from the DAC 25 with the pixel signal SIG, and outputs an output signal VCO indicating a comparison result. When the reference signal REF and the pixel signal SIG are the same (the same voltage), the comparison circuit 51 inverts the output signal VCO.

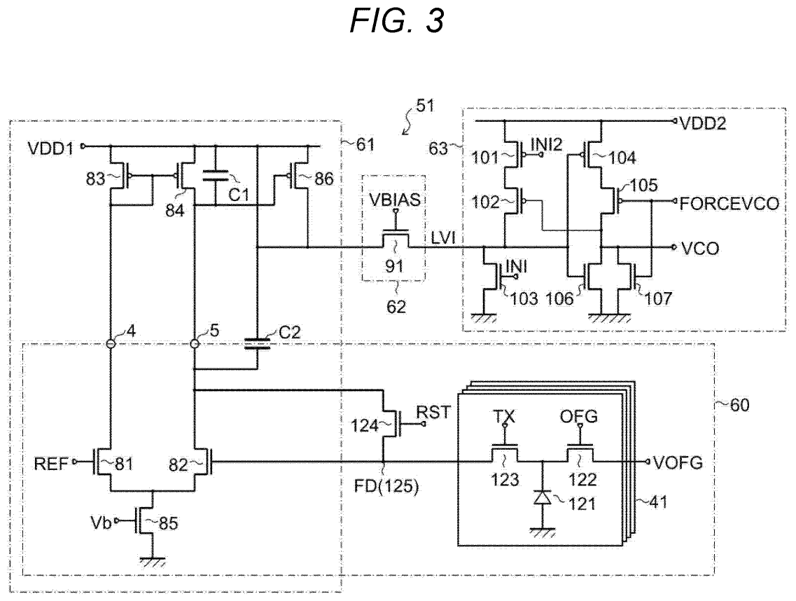

The comparison circuit 51 includes a differential input circuit 61, a voltage conversion circuit 62, and a positive feedback (PFB) circuit 63. A specific configuration of the comparison circuit 51 will be described later with reference to FIG. 3.

In addition to the input of the output signal VCO from the comparison circuit 51, a WR signal (hereinafter also referred to as a write control signal WR) indicating a pixel signal write operation, an RD signal (hereinafter also referred to as a read control signal RD) indicating a pixel signal read operation, and a WORD signal for controlling the timing to read the pixel 21 during a pixel signal read operation are supplied from the vertical drive circuit 27 to the data storage unit 52. Further, time codes generated by the time code generation units 26 are also supplied via the time code transfer units 23.

The data storage unit 52 includes a latch control circuit (storage control unit) 71 that controls time code write and read operations on the basis of the WR signal and the RD signal, and a latch storage unit 72 that stores a time code.

In a time code write operation, the latch control circuit 71 stores the time code, which is supplied from the time code transfer units 23 and is updated every unit time, into the latch storage unit 72, while a high-level output signal VCO is input from the comparison circuit 51. Further, when the reference signal REF and the pixel signal SIG are the same (voltage), and the output signal VCO supplied from the comparison circuit 51 is inverted to the low level, writing (updating) of the supplied time code is stopped, and the time code last stored into the latch storage unit 72 is held in the latch storage unit 72. The time code stored in the latch storage unit 72 indicates the time at which the pixel signal SIG and the reference signal REF become equal, and represents data indicating that the pixel signal SIG was the reference voltage at that time, which is the digitized value of the amount of light.

After the sweep of the reference signal REF is completed, and the time codes are stored into the latch storage units 72 of all the pixels 21 in the pixel array unit 22, the operation of the pixels 21 is changed from the write operation to a read operation.

In the time code read operation, on the basis of the read control signal RD and the WORD signal for controlling the read timing, the latch control circuit 71 outputs the time code (digital pixel signal) stored in the latch storage unit 72 to the time code transfer unit 23 when the pixel 21 reaches its own read timing. The time code transfer unit 23 sequentially transfers the supplied time codes in a reading direction (a column direction (vertical direction) toward the output unit 28 in FIG. 1), and supplies the time codes to the output unit 28. In some cases, the time code transfer unit 23 transfers time codes in units of clusters including a plurality of pixels arranged adjacent to each other.

### Example of a Specific Configuration of the Pixel Circuit

Referring now to FIG. 3, a specific configuration of the pixel circuit 41 is described. FIG. 3 is a circuit diagram illustrating the details of the pixel circuit 41 and the comparison circuit 51 illustrated in FIG. 2.

The pixel circuit 41 includes a photodiode (PD) 121 as a photoelectric conversion element, a discharge transistor 122, a transfer transistor 123, a reset transistor 124, and a floating diffusion layer (FD) 125. The ground node VSS' for the pixel circuit 41 is separated from the differential input circuit 61 in the comparison circuit 51 and the ground node VSS of the positive feedback circuit 63. Although FIG. 3 illustrates an example in which a plurality of pixel circuits 41 shares one FD 125, FDs 125 may be provided for the respective pixel circuits 41.

The discharge transistor 122 is used in a case where the exposure period is adjusted. Specifically, if the discharge transistor 122 is turned on when the exposure period is to start at desired timing, the electric charge accumulated in the photodiode 121 until that point of time is discharged, and thus, the exposure period is started after the discharge transistor 122 is turned off.

The transfer transistor 123 transfers the charge generated by the photodiode 121 to the FD 125. The reset transistor 124 resets the charge held in the FD 125. The FD 125 is connected to the gate of a transistor 82 of the differential input circuit 61. Thus, the transistor 82 of the differential input circuit 61 also functions as an amplification transistor of the pixel circuit 41.

The source of the reset transistor 124 is connected to the gate of the transistor 82 of the differential input circuit 61 and the FD 125, and the drain of the reset transistor 124 is connected to the drain of the transistor 82. Therefore, there is no fixed reset voltage for resetting the charge of the FD 125. This is because the reset voltage for resetting the FD 125 can be set as appropriate with the use of the reference signal REF by controlling the circuit state of the differential input circuit 61.

The comparison circuit 51 includes the differential input circuit 61, the voltage conversion circuit 62, and the positive feedback circuit 63.

The differential input circuit 61 compares the pixel signal SIG output from the pixel circuit 41 in the pixel 21 with the reference signal REF output from the DAC 25, and outputs a predetermined signal (current) when the pixel signal SIG is higher than the reference signal REF.

The differential input circuit 61 includes transistors 81 and 82 forming a differential pair, transistors 83 and 84 constituting a current mirror, a transistor 85 as a constant current source that supplies a current IB corresponding to an input bias current Vb, and a transistor 86 that outputs an output signal HVO of the differential input circuit 61.

The transistors 81, 82, and 85 are negative channel MOS (NMOS) transistors, and the transistors 83, 84, and 86 are positive channel MOS (PMOS) transistors.

In the transistors 81 and 82 as a differential pair, the reference signal REF output from the DAC 25 is input to the gate of the transistor 81, and the pixel signal SIG output from the pixel circuit 41 in the pixel 21 is input to the gate of the transistor 82. The sources of the transistors 81 and 82 are connected to the drain of the transistor 85, and the source of the transistor 85 is connected to a predetermined voltage VSS (VSS<VDD2<VDD1).

The drain of the transistor 81 is connected to the gates of the transistors 83 and 84 constituting a current mirror circuit and the drain of the transistor 83, and the drain of the transistor 82 is connected to the drain of the transistor 84 and the gate of the transistor 86. The sources of the transistors 83, 84, and 86 are connected to a first power supply voltage VDD1.

The voltage conversion circuit 62 is an NMOS transistor 91, for example. The drain of the transistor 91 is connected to the drain of the transistor 86 of the differential input circuit 61, the source of the transistor 91 is connected to a predetermined connection point in the positive feedback circuit 63, and the gate of the transistor 91 is connected to a bias voltage VBIAS.

The transistors 81 to 86 constituting the differential input circuit 61 are a circuit that operates at a high voltage up to the first power supply voltage VDD1, and the positive feedback circuit 63 is a circuit that operates at a second power supply voltage VDD2 lower than the first power supply voltage VDD1. The voltage conversion circuit 62 converts the output signal HVO input from the differential input circuit 61 into a low-voltage signal (converted signal) LVI with which the positive feedback circuit 63 can operate, and supplies the signal to the positive feedback circuit 63.

The bias voltage VBIAS may be any voltage that is to be converted into a voltage that does not destroy each of the transistors 101 to 105 of the positive feedback circuit 63 operating at a constant voltage. For example, the bias voltage VBIAS can be the same voltage as the second power supply voltage VDD2 of the positive feedback circuit 63 (VBIAS=VDD2), and a similar voltage conversion effect can be achieved even if VCO is connected thereto.

The positive feedback circuit 63 outputs a comparison result signal that is to be inverted when the pixel signal SIG is higher than the reference signal REF, on the basis of the converted signal LVI obtained by converting the output signal HVO from the differential input circuit 61 into a signal corresponding to the second power supply voltage VDD2. Further, the positive feedback circuit 63 increases the transition speed at the time when the output signal VCO to be output as the comparison result signal is inverted.

The positive feedback circuit 63 includes five transistors 101 to 107. Here, the transistors 101, 102, 104, and 105 are PMOS transistors, and the transistors 103, 106, and 107 are NMOS transistors.

The source of the transistor 91, which is an output terminal of the voltage conversion circuit 62, is connected to the drains of the transistors 102 and 103 and the gates of the transistors 104 and 106. The sources of the transistors 101 and 104 are connected to the second power supply voltage VDD2, the drain of the transistor 101 is connected to the source of the transistor 102, and the gate of the transistor 102 is connected to the drains of the transistors 105 and 107, which are also output terminals of the positive feedback circuit 63. The sources of the transistors 103, 106, and 107 are connected to the predetermined voltage VSS. An initialization signal INI2 is supplied to the gate of the transistor 101, and an initialization signal INI is supplied to the gate of the transistor 103.

A FORCEVCO signal is input to the gates of the transistors 105 and 107. When the FORCEVCO signal is at the high level, the transistor 107 is turned on, and the VCO signal switches to the low level.

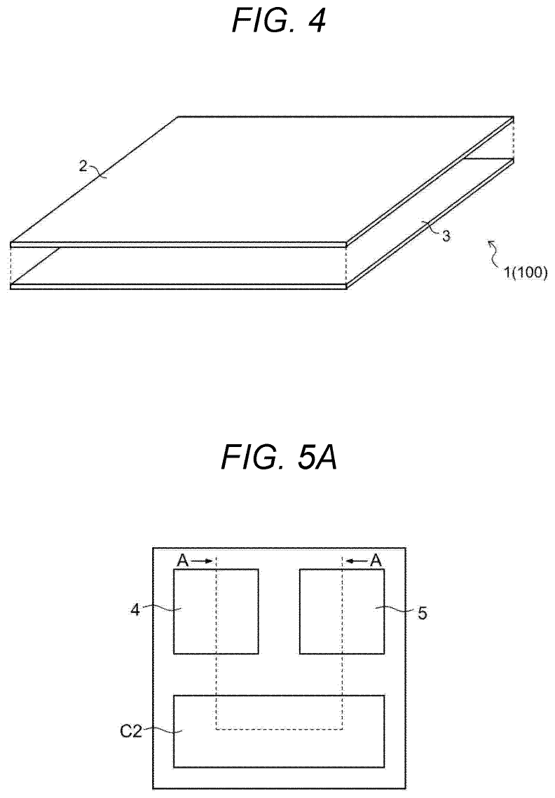

The semiconductor device 1 including the solid-state imaging device 100 according to the present embodiment can be formed by stacking two chips. FIG. 4 is a diagram illustrating an example in which a pixel chip (first substrate) 2 and a logic chip (second substrate) 3 are stacked to form the solid-state imaging device 100. The pixel chip 2 is disposed on the light incident surface side, and the logic chip 3 is disposed on the lower side of the pixel chip 2, which is the surface side opposite to the light incident surface. The pixel chip 2 and the logic chip 3 are bonded by Cu—Cu bonding, for example.

In the pixel chip 2, the pixel array unit 22 having a plurality of pixels 21 arranged therein and the like are disposed. In the logic chip 3, the pixel drive circuit 24, the D/A converter (DAC) 25, the time code generation units 26, the vertical drive circuit 27, the output unit 28, the timing generation circuit 29, and the like are disposed. For example, the circuits within the range of a frame 60 in FIG. 3 are disposed in the pixel chip 2, and the circuits other than the frame 60 are disposed in the logic chip 3.

The drain of the transistor 81 in the pixel chip 2, and the source of the transistor 83 and the gate of the transistor 84 in the logic chip 3 are electrically connected by Cu—Cu bonding (hereinafter referred to as first Cu—Cu bonding), for example. This Cu—Cu bonding region is referred to as a first Cu—Cu bonding region 4.

Likewise, the drain of the transistor 82 in the pixel chip 2, and the source of the transistor 84 and the gate of the transistor 86 in the logic chip 3 are electrically connected by Cu—Cu bonding (hereinafter referred to as second Cu—Cu bonding), for example. This Cu—Cu bonding region is referred to as a second Cu—Cu bonding region 5.

Two capacitors C1 and C2 are connected in parallel between the source and the drain of the transistor 86. These two capacitors C1 and C2 act to reduce random noise. In the present specification, these two capacitors C1 and C2 are referred to as a first capacitor C1 and a second capacitor C2. The first capacitor C1 is disposed in the logic chip 3, and the second capacitor C2 is disposed in the vicinity of the Cu—Cu bonding surface between the pixel chip 2 and the logic chip 3.

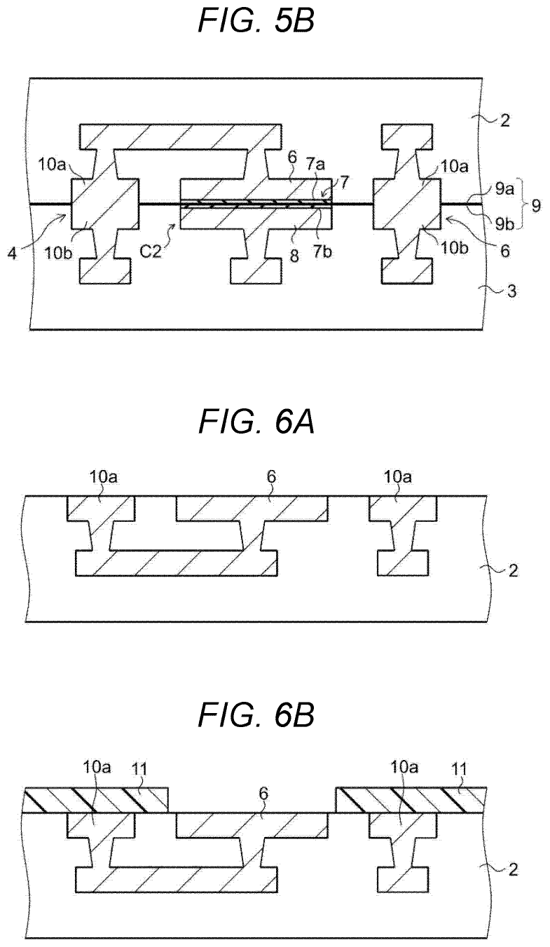

FIG. 5A is a schematic plan view of the vicinity of the bonding surface between the pixel chip 2 and the logic chip 3, and FIG. 5B is a cross-sectional view taken along the line A-A defined in FIG. 5A. FIGS. 5A and 5B show the first Cu—Cu bonding region 4, the second Cu—Cu bonding region 5, and the second capacitor C2 described above.

As illustrated in FIG. 5A, in addition to the first Cu—Cu bonding region 4 and the second Cu—Cu bonding region 5, a large number of Cu—Cu bonding regions are provided on the bonding surface between the pixel chip 2 and the logic chip 3, but there is a free region in which these Cu—Cu bonding regions are not provided on the bonding surface. The second capacitor C2 is disposed in this free region.

As illustrated in FIG. 5B, the second capacitor C2 has a structure in which a first electrode 6, an oxide layer 7, and a second electrode 8 are stacked, for example. The first electrode 6 is disposed on the side of the pixel chip 2, and the second electrode 8 is arranged on the side of the logic chip 3. The oxide layer 7 may be a single layer, or may be a laminate formed with a plurality of oxide layers 7.

In addition to the above oxide layer 7, an insulating film 9 may be disposed between the first electrode 6 and the second electrode 8. The insulating film 9 contains an oxide, a nitride, or a metal oxide, for example. The insulating film 9 is assumed to be thinner than the oxide layer 7.

The oxide layer 7 may be a laminate including a first oxide layer 7a obtained by oxidizing the surface of the first electrode 6, and a second oxide layer 7b obtained by oxidizing the surface of the second electrode 8. The insulating film 9 described above may be disposed between the first oxide layer 7a and the second oxide layer 7b. The insulating film 9 is assumed to be thinner than the first oxide layer 7a and the second oxide layer 7b.

The insulating film 9 may be a laminate including a first insulating film 9a and a second insulating film 9b. In this case, the first insulating film 9a and the second insulating film 9b are disposed between the first oxide layer 7a and the second oxide layer 7b. Both the first insulating film 9a and the second insulating film 9b are thinner than the first oxide layer 7a, and are thinner than the second oxide layer 7b. The first insulating film 9a and the second insulating film 9b may contain an oxide, a nitride, or a metal oxide.

As illustrated in FIG. 5B, the second capacitor C2 is disposed along the bonding surface between the pixel chip 2 and the logic chip 3, and a plurality of Cu—Cu bonding regions such as the first Cu—Cu bonding region 4 and the second Cu—Cu bonding region 5 is disposed in the vicinity of the bonding surface.

These Cu—Cu bonding regions 4 and 5 are regions in which a first Cu layer (first conductive layer) 10a in the pixel chip 2 and a second Cu layer (second conductive layer) 10b in the logic chip 3 are disposed to face each other and are directly bonded. The first electrode 6 forming the second capacitor C2 is disposed at the same layer height as the first Cu layer 10a, and the first electrode 6 can be formed in the manufacturing process of forming the first Cu layer 10a. Likewise, the second electrode 8 forming the second capacitor C2 is disposed at the same layer height as the second Cu layer 10b, and the second electrode 8 can be formed in the manufacturing process of forming the second Cu layer 10b.

The first electrode 6 and the second electrode 8 constituting the second capacitor C2, and the first Cu layer (first conductive layer) 10a and the second Cu layer (second conductive layer) 10b constituting the Cu—Cu bonding regions may contain the same metal material. Alternatively, the metal material (first metal material) of the first electrode 6 and the second electrode 8 may be different from the metal material (second metal material) of the first Cu layer (first conductive layer) 10a and the second Cu layer (second conductive layer) 10b. In this case, the first metal material is desirably a material that is less likely to cause thermal diffusion than the second metal material, as described later.

### (Process of Manufacturing the Second Capacitor C2)

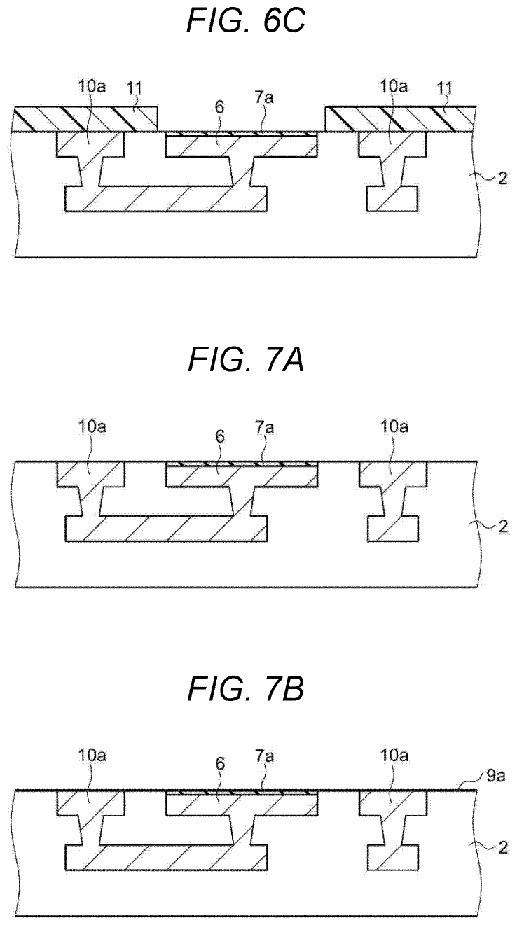

FIGS. 6A to 10B are process cross-sectional views illustrating the process of manufacturing the second capacitor C2. FIGS. 6A to 10B illustrate a cross-section structure of part of wiring layers of the pixel chip 2 and the logic chip 3.

First, as illustrated in FIG. 6A, the first electrode 6 and the first Cu layer 10a are formed in the wiring layer of the pixel chip 2. Next, as illustrated in FIG. 6B, except for the first electrode 6, the upper surface of the first Cu layer 10a is covered with a resist 11. Note that the upper surface of the first Cu layer 10a is a surface disposed to face the logic chip 3. The upper surface of the first Cu layer 10a is covered with the resist 11 so that the surface of the first Cu layer 10a is not oxidized.

Next, as illustrated in FIG. 6C, the upper surface of the first electrode 6 is subjected to oxidation treatment. As a result, the first oxide layer 7a is formed on the upper surface of the first electrode 6. The first oxide layer 7a is an oxide of the first electrode 6, and has a thickness within the range of 1 to 10 nm, for example. Thus, only the upper surface portion of the first electrode 6 turns into the first oxide layer 7a.

Next, as illustrated in FIG. 7A, the resist 11 is removed by etching or the like. In this state, since the upper surface of the pixel chip 2 is not necessarily flat, the entire upper surface of the pixel chip 2 is covered with the thin first insulating film 9a as illustrated in FIG. 7B. As the method for forming the first insulating film 9a, an atomic layer deposition (ALD) method or the like is used, for example. This first insulating film 9a is a film thinner than the first oxide layer 7a. Specifically, the first insulating film 9a has a thickness within the range of 0.1 to 1 nm.

As the upper surface of the pixel chip 2 is covered with the first insulating film 9a, the upper surface of the pixel chip 2 can be planarized. As will be described later, the upper surface of the pixel chip 2 is disposed to face the upper surface of the logic chip 3, and is bonded by Cu—Cu bonding. However, the upper surfaces of both chips are planarized in advance, so that voids do not appear in the bonding surface at the time of Cu—Cu bonding, and conductive performance can be enhanced.

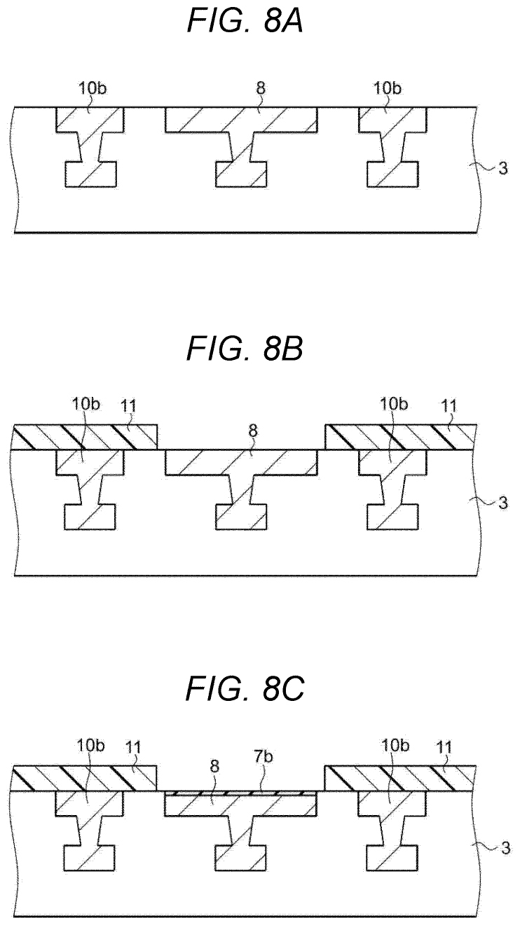

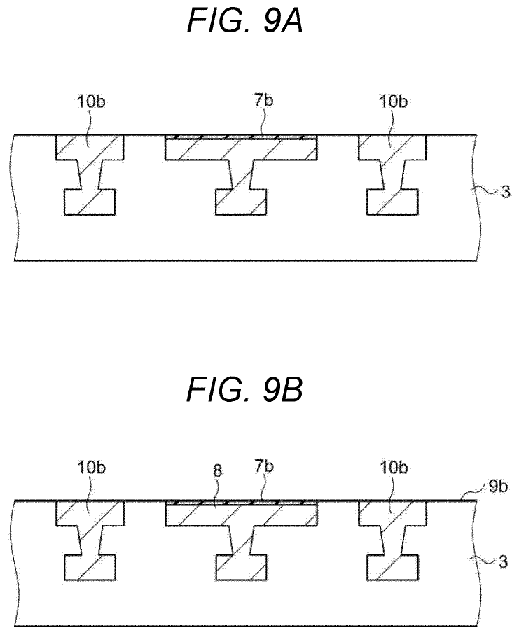

Before and after the processes illustrated in FIGS. 6 and 7, processing of the wiring layer of the logic chip 3 is performed. Specifically, as illustrated in FIG. 8A, the second electrode 8 and the second Cu layer 10b are formed in the wiring layer of the logic chip 3. Next, as illustrated in FIG. 8B, except for the second electrode 8, the upper surface of the second Cu layer 10b is covered with the resist 11. Next, as illustrated in FIG. 8C, the upper surface of the second electrode 8 is subjected to an oxidation treatment, to form the second oxide layer 7b, which is an oxide of the second electrode 8. The thickness of the second oxide layer 7b is substantially the same as that of the first oxide layer 7a. Next, as illustrated in FIG. 9A, the resist 11 is removed. Next, as illustrated in FIG. 9B, the entire upper surface of the logic chip 3 is covered with the thin second insulating film 9b. The thickness of the second insulating film 9b is substantially the same as the thickness of the first insulating film 9a.

Through the above processes, the processing of the wiring layer of the pixel chip 2 and the processing of the wiring layer of the logic chip 3 are completed, and the process of bonding both chips is next performed.

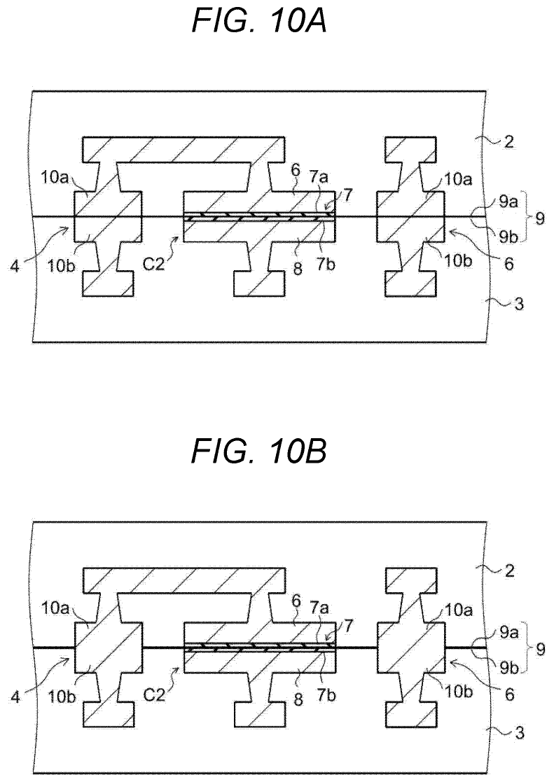

Specifically, as illustrated in FIG. 10A, the upper surfaces of the pixel chip 2 and the logic chip 3 are brought into contact with each other while facing each other. As a result, the first insulating film 9a of the pixel chip 2 and the second insulating film 9b of the logic chip 3 are brought into contact with each other, and heat treatment is performed in this state. As the heat treatment is performed, the first Cu layer 10a and the second Cu layer 10b break through the thin first insulating film 9a and second insulating film 9b in between, and diffuse into each other, to secure electrical conduction, as illustrated in FIG. 10B.

On the other hand, the first oxide layer 7a and the second oxide layer 7b thicker than the first insulating film 9a and the second insulating film 9b are disposed between the first electrode 6 and the second electrode 8. Accordingly, the metal materials of the first electrode 6 and the second electrode 8 do not break through the first oxide layer 7a and the second oxide layer 7b, and the oxide layer 7 remains between the first electrode 6 and the second electrode 8.

Through the above processes, the plurality of Cu—Cu bonding regions including the first Cu—Cu bonding region 4 and the second Cu—Cu bonding region 5, and the second capacitor C2 are formed along the bonding surface between the pixel chip 2 and the logic chip 3.

The first insulating film 9a and the second insulating film 9b for planarizing the upper surfaces of the pixel chip 2 and the logic chip 3 may not be oxide films formed by the ALD method or the like, but may be nitride films or may be metal oxide films formed with a high-k material. In FIGS. 7B and 9B, the first insulating film 9a and the second insulating film 9b are formed on both the side of the pixel chip 2 and the side of the logic chip 3, but either one of the insulating films may be omitted.

### (First Modification)

In the process of manufacturing the semiconductor device 1 illustrated in FIGS. 6A to 10B, after the first oxide layer 7a and the second oxide layer 7b are formed on the first electrode 6 and the second electrode 8, and the resist 11 is removed, the first insulating film 9a and the second insulating film 9b are formed on the upper surfaces of the pixel chip 2 and the logic chip 3, respectively. However, in a case where the upper surfaces of the pixel chip 2 and the logic chip 3 are flat at the stage of removal of the resist 11, the process of forming the first insulating film 9a and the second insulating film 9b may be omitted.

FIG. 11 is a cross-sectional view illustrating an eventual cross-section structure of a semiconductor device 1 according to a first modification in which the process of forming the first insulating film 9a and the second insulating film 9b is omitted. Compared with that in FIG. 10B, the insulating film 9 including the first insulating film 9a and the second insulating film 9b is omitted in FIG. 11. In a case where the pixel chip 2 and the logic chip 3 are brought into contact with each other for heat treatment without formation of the first insulating film 9a and the second insulating film 9b, if the upper surfaces of the pixel chip 2 and the logic chip 3 are not flat, voids appear when both chips are brought into contact with each other, and electrical conduction might be incomplete. Therefore, in a case where the process of manufacturing the first insulating film 9a and the second insulating film 9b is omitted as illustrated in FIG. 11, both the chips may be bonded after some planarization process such as chemical mechanical polishing (CMP).

### (Second Modification)

In the process of manufacturing the semiconductor device 1 illustrated in FIGS. 6A to 10B, the first oxide layer 7a is formed on the upper surface of the first electrode 6 in the wiring layer of the pixel chip 2, and the second oxide layer 7b is formed on the upper surface of the second electrode 8 in the wiring layer of the logic chip 3. However, only one of the first oxide layer 7a and the second oxide layer 7b may be formed, and the other may be omitted.

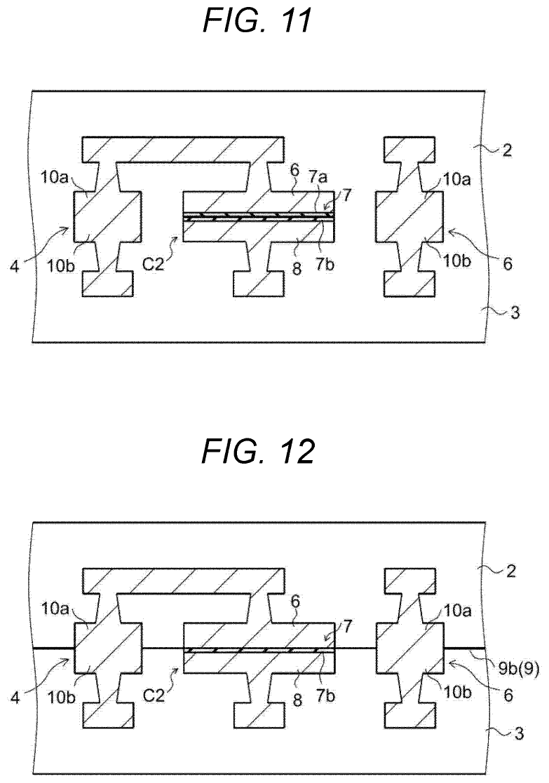

FIG. 12 is a cross-sectional view of a semiconductor device 1 according to a second modification in which the process of forming the first oxide layer 7a on the side of the pixel chip 2 is omitted. In the case illustrated in FIG. 12, the second oxide layer 7b is formed on the upper surface of the second electrode 8 in the wiring layer of the logic chip 3, and the second insulating film 9b is further formed thereon. On the other hand, the first electrode 6 in the wiring device of the pixel chip 2 is bonded to the logic chip 3 while remaining exposed. As a result, the second oxide layer 7b and the second insulating film 9b are disposed between the first electrode 6 and the second electrode 8, and the first oxide layer 7a and the first insulating film 9a are omitted. Thus, the capacitance of the second capacitor C2 becomes higher than that in the case where the first oxide layer 7a and the first insulating film 9a are provided.

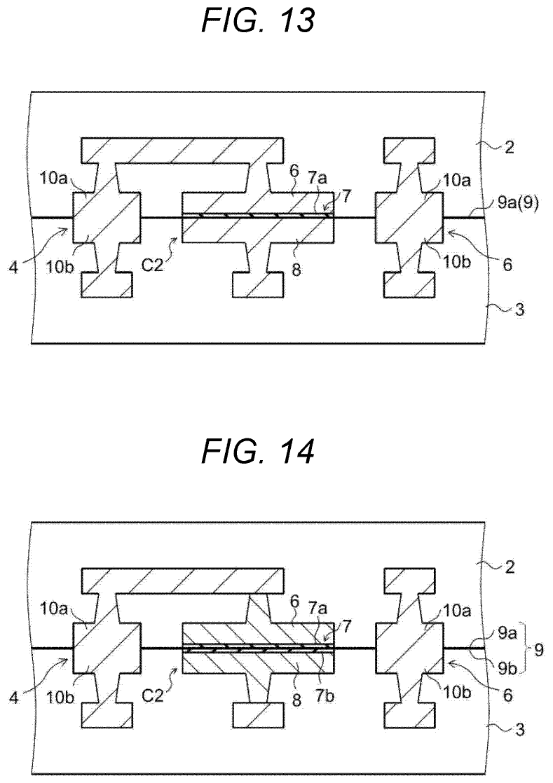

FIG. 13 is a cross-sectional view of a semiconductor device 1 according to the second modification in which the process of forming the second oxide layer 7b on the side of the logic chip 3 is omitted. In the case illustrated in FIG. 13, the first oxide layer 7a is formed on the upper surface of the first electrode 6 in the wiring layer of the pixel chip 2, and the first insulating film 9a is further formed thereon. On the other hand, the second electrode 8 in the wiring device of the logic chip 3 is bonded to the pixel chip 2 while remaining exposed. As a result, the first oxide layer 7a and the first insulating film 9a are disposed between the first electrode 6 and the second electrode 8, and the second oxide layer 7b and the second insulating film 9b are omitted. Thus, the capacitance of the second capacitor C2 becomes higher than that in the case where the second oxide layer 7b and the second insulating film 9b are provided.

### (Third Modification)

The metal material of the layer of the first electrode 6 and the layer of the second electrode 8 constituting the second capacitor C2 is not necessarily Cu. Cu is likely to cause thermal diffusion when heat treatment is performed. Accordingly, even if the insulating film 9 is disposed in a Cu—Cu bonding region, Cu breaks through the insulating film 9 and diffuses, and conductivity is secured. On the other hand, the layer of the first electrode 6 and the layer of the second electrode 8 constituting the second capacitor C2 need to maintain the oxide layer 7 in between. Therefore, the material of the layer of the first electrode 6 and the layer of the second electrode 8 is desirably a material that is less likely to thermally diffuse than Cu.

FIG. 14 is a cross-sectional view of a semiconductor device 1 according to a third modification. FIG. 14 illustrates an example in which the first electrode 6 and the second electrode 8 of the second capacitor C2 are formed with a metal material different from copper, which is a metal material of the Cu—Cu bonding regions such as the first Cu—Cu bonding region 4 and the second Cu—Cu bonding region 5. As the metal material of the first electrode 6 and the second electrode 8, a metal that hardly causes thermal diffusion (aluminum or the like, for example) is selected. As a result, even if a thermal diffusion process is performed after the first insulating film 9a and the second insulating film 9b are formed to planarize the surfaces of the pixel chip 2 and the logic chip 3, the metal material of the first electrode 6 and the second electrode 8 is not thermally diffused, and fluctuations in the capacitance of the second capacitor C2 can be suppressed.

Note that, to make the material of the first electrode 6 and the second electrode 8 a material other than copper, a Cu layer is first formed in the Cu—Cu bonding regions before the processes illustrated in FIGS. 6A and 8A, the Cu layer is then covered with the resist 11, an Al layer or the like is formed at the locations of formation of the first electrode 6 and the second electrode 8, the resist 11 is removed, and the manufacturing processes illustrated in FIGS. 6B and 8B and the subsequent processes are performed.

In the example described in the above embodiment, the semiconductor device 1 including the solid-state imaging device 100 is formed with the pixel chip 2 and the logic chip 3, these chips are bonded by Cu—cu bonding, and the capacitor (second capacitor C2) is formed along the bonding surface between these chips. However, the semiconductor device 1 according to the present embodiment may have functions other than those of the solid-state imaging device 100. That is, the semiconductor device 1 according to the present embodiment is only required to include a first substrate including the first electrode 6, a second substrate including the second electrode 8 disposed to face the first electrode 6, and the oxide layer 7 disposed between the first electrode 6 and the second electrode 8. In this case, the oxide layer 7 is an oxide layer of the first electrode 6 or the second electrode 8. Therefore, the semiconductor device 1 of the present disclosure does not necessarily include the solid-state imaging device 100.

As described above, in the present embodiment, the process of forming the Cu—Cu bonding regions is used to form a capacitor (second capacitor C2) in a free region of the Cu—Cu bonding regions provided along the bonding surface between the first substrate such as the pixel chip 2 and the second substrate such as the logic chip 3. Thus, a capacitor having a desired capacitance can be formed, without an increase in the mounting area and addition of a manufacturing process.

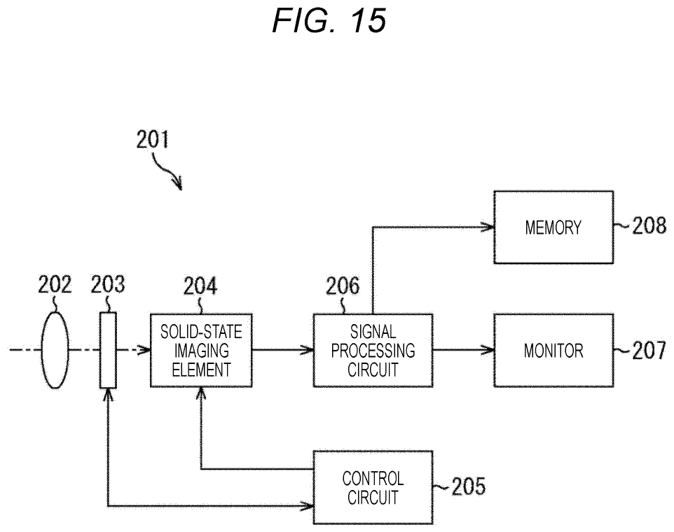

The solid-state imaging device 100 according to the present embodiment can be included in various electronic devices 201. FIG. 15 is a block diagram illustrating a schematic configuration of an electronic device 201. The electronic device 201 in FIG. 15 is an imaging device such as a digital still camera or a digital video camera, a smartphone having an imaging function, a portable telephone, a tablet, a personal computer (PC), or the like, for example.

The electronic device 201 in FIG. 15 includes an optical system 202, a shutter device 203, a solid-state imaging element 204, a drive circuit 205, a signal processing circuit 206, a monitor 207, and a memory 208, and can capture at least one of a still image and a moving image.

The optical system 202 includes one or a plurality of lenses, guides light (incident light) from a subject to the solid-state imaging element 204, and causes imaging on the light receiving surface of the solid-state imaging element 204.

The shutter device 203 is disposed between the optical system 202 and the solid-state imaging element 204, and controls the light irradiation period and the light blocking period for the solid-state imaging element 204, under the control of the drive circuit 205.

The solid-state imaging element 204 has functions similar to those of the solid-state imaging device 100 according to the present embodiment described above. The solid-state imaging element 204 stores signal charge for a certain period, in accordance with the light forming an image on the light receiving surface via the optical system 202 and the shutter device 203. The signal charge stored in the solid-state imaging element 204 is transferred in accordance with a drive signal (timing signal) supplied from the drive circuit 205.

The drive circuit 205 outputs the drive signal that controls a transfer operation of the solid-state imaging element 204 and a shutter operation of the shutter device 203, to drive the solid-state imaging element 204 and the shutter device 203.

The signal processing circuit 206 performs various kinds of signal processing on the signal charge output from the solid-state imaging element 204. An image (image data) obtained by the signal processing circuit 206 performing the signal processing is supplied to and is displayed on the monitor 207, or is supplied to and is stored (recorded) into the memory 208.

In the electronic device 201 designed as described above, the solid-state imaging element 204 is disposed on the first substrate, the signal processing circuit 206 is disposed on the second substrate, and the capacitor (second capacitor C2) is formed in a free region of the Cu—Cu bonding regions provided along the bonding surface of the second substrate through the process of forming the Cu—Cu bonding region. Thus, a capacitor having a desired capacitance can be formed, without an increase in the mounting area and addition of a manufacturing process.

### Example Applications

The technology according to the present disclosure can be applied to various products. For example, the technology according to the present disclosure may also be implemented as a device mounted on any kind of moving body such as an automobile, an electric automobile, a hybrid electric automobile, a motorcycle, a bicycle, a personal mobility, an airplane, a drone, a ship, a robot, a construction machine, or an agricultural machine (tractor).

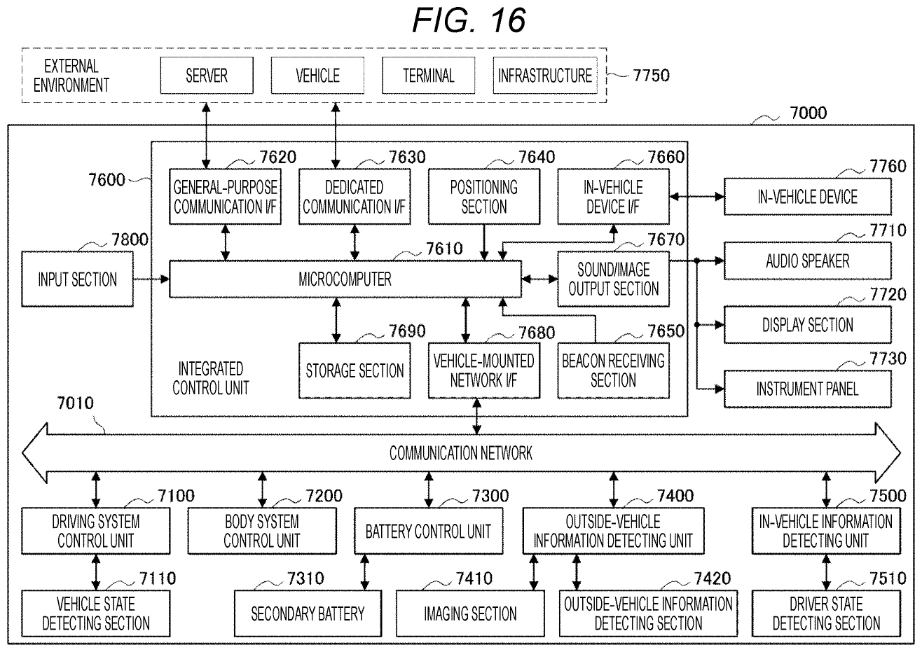

FIG. 16 is a block diagram illustrating an example of a schematic configuration of a vehicle control system 7000 that is an example of a moving body control system to which the technology according to the present disclosure can be applied. The vehicle control system 7000 includes a plurality of electronic control units connected to each other via a communication network 7010. In the example illustrated in FIG. 16, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. Functional components of the integrated control unit 7600 illustrated in FIG. 16 include a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

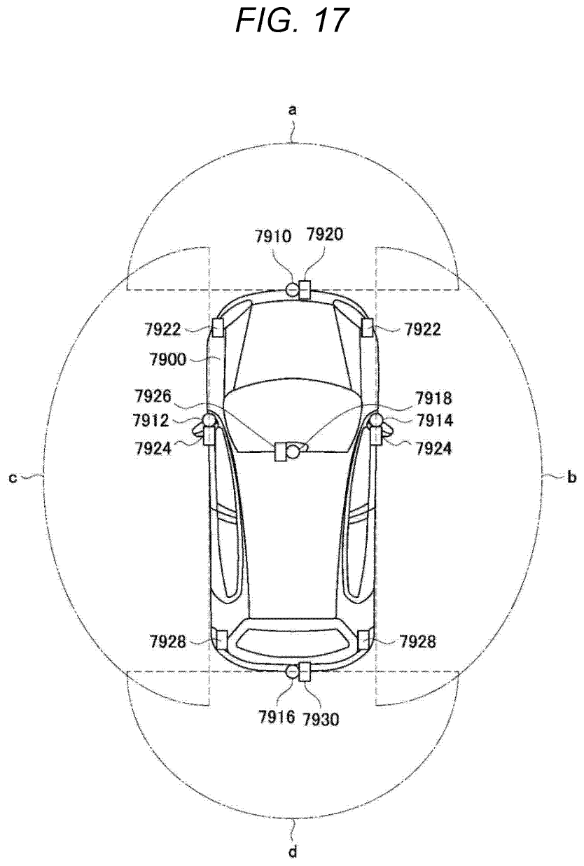

Here, FIG. 17 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 17 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 16, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750.

The general-purpose communication I/F 7620 may implement a cellular communication protocol such as global system for mobile communications (GSM (registered trademark)), WiMAX (registered trademark), long term evolution (LTE (registered trademark)), or LTE-advanced (LTE-A), or some other wireless communication protocol such as wireless LAN (also referred to as wireless fidelity (Wi-Fi (registered trademark)), or Bluetooth (registered trademark). The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 16, an audio speaker 7710, a display section 7720, and an instrument panel 7730 are shown as examples of the output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 16, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for realizing each function of the semiconductor device 1 according to the present embodiment described with reference to FIGS. 1 to 4 and others can be mounted on any control unit or the like. Furthermore, a computer-readable recording medium in which such a computer program is stored can be provided. The recording medium is a magnetic disk, an optical disk, a magneto-optical disk, a flash memory, or the like, for example. Alternatively, the computer program described above may be distributed via a network, for example, without the use of any recording medium.

In the vehicle control system 7000 described above, the semiconductor device 1 according to the present embodiment described with reference to FIGS. 1 to 3 and others can be applied to the imaging section 7410 and the integrated control unit 7600 of the example application illustrated in FIG. 16. For example, a processing operation of the semiconductor device 1 can be performed by the microcomputer 7610, the storage section 7690, and the vehicle-mounted network I/F 7680 of the integrated control unit 7600.

Furthermore, at least some of the components of the semiconductor device 1 described with reference to FIGS. 1 to 4 and others may be implemented in a module (an integrated circuit module formed with a single die, for example) for the integrated control unit 7600 illustrated in FIG. 16. Alternatively, the semiconductor device 1 described with reference to FIGS. 1 to 4 and others may be implemented by a plurality of control units of the vehicle control system 7000 illustrated in FIG. 16.

Note that the present technology may have the following configurations.
(1) A semiconductor device including:
a first substrate including a first electrode;
a second substrate including a second electrode disposed to face the first electrode; and
an oxide layer of at least one of the first electrode or the second electrode, the oxide layer being disposed between the first electrode and the second electrode.
(2) The semiconductor device according to (1), in which a capacitor includes the first electrode, the oxide layer, and the second electrode.
(3) The semiconductor device according to (1) or (2), further including an insulating film that is disposed at least between the first electrode and the oxide layer or between the second electrode and the oxide layer, and is thinner than the oxide layer.
(4) The semiconductor device according to (3), in which the insulating film contains one of an oxide, a nitride, or a metal oxide.
(5) The semiconductor device according to (2), in which
the oxide layer includes:
a first oxide layer formed by oxidizing a surface of the first electrode; and
a second oxide layer formed by oxidizing a surface of the second electrode, and
the capacitor includes the first electrode, the first oxide layer, the second oxide layer, and the second electrode.
(6) The semiconductor device according to (5), further including a first insulating film and a second insulating film that are stacked between the first oxide layer and the second oxide layer, in which
the first insulating film and the second insulating film are thinner than the first oxide layer and the second oxide layer.
(7) The semiconductor device according to (6), in which the first insulating film and the second insulating film contain one of an oxide, a nitride, or a metal oxide.
(8) The semiconductor device according to any one of (1) to (7), further including:
a first conductive layer that is disposed at the same layer height as the first electrode and at a distance from the first electrode; and
a second conductive layer that is disposed at the same height as the second electrode and at a distance from the second electrode, in which
the first conductive layer and the second conductive layer are disposed to face each other and are joined to each other.
(9) The semiconductor device according to (8), in which the first electrode, the second electrode, the first conductive layer, and the second conductive layer contain the same metal material.
(10) The semiconductor device according to (8), in which
the first electrode and the second electrode contain a first metal material, and
the first conductive layer and the second conductive layer contain a second metal material different from the first metal material.
(11) The semiconductor device according to (10), in which the first metal material is a material that is less likely to cause thermal diffusion than the second metal material.
(12) The semiconductor device according to any one of (1) to (11), in which the oxide layer has a thickness that is not smaller than 1 nm and not greater than 10 nm.
(13) The semiconductor device according to (3) or (4), in which the insulating film has a thickness that is not smaller than 0.1 nm and not greater than 1 nm.
(14) The semiconductor device according to (6) or (7), in which each of the first insulating film and the second insulating film has a thickness that is not smaller than 0.1 nm and not greater than 1 nm.
(15) The semiconductor device according to (2), in which
the first substrate includes a plurality of pixels that perform photoelectric conversion,
the second substrate includes a signal processing circuit that performs signal processing on a pixel signal photoelectrically converted by the plurality of pixels, and
the pixels each include:
a photoelectric conversion element,
an analog-digital converter that compares an electric signal photoelectrically converted by the photoelectric conversion element with a reference signal, and outputs a signal indicating a comparison result, and
the capacitor.
(16) The semiconductor device according to (15), in which the capacitor is disposed within a region of a corresponding pixel on a bonding surface between the first substrate and the second substrate.
(17) A method for manufacturing a semiconductor device, the method including:
a step of forming a first conductive layer and a first electrode on a first substrate;
a step of forming a second conductive layer and a second electrode on a second substrate;
a step of forming an oxide layer by oxidizing a surface of at least one of the first electrode or the second electrode; and
a step of forming a capacitor including the first electrode, the oxide layer, and the second electrode by disposing the first conductive layer and the second conductive layer to face each other, bringing the first conductive layer and the second conductive layer into contact with each other, joining the first conductive layer and the second conductive layer, and disposing the first electrode and the second electrode to face each other.
(18) The method for manufacturing a semiconductor device according to (17), further including a step of forming an insulating film on a surface of at least one of the first substrate or the second substrate, on which the oxide layer is formed, the insulating film being thinner than the oxide layer.
(19) The method for manufacturing a semiconductor device according to (18), in which the step of forming the oxide layer includes:
a step of forming a first oxide layer by oxidizing a surface of the first electrode; and
a step of forming a second oxide layer by oxidizing a surface of the second electrode;
the step of forming the insulating film includes:
a step of forming a first insulating film on a surface of the first oxide layer, the first insulating film being thinner than the first oxide layer; and
a step of forming a second insulating film on a surface of the second oxide layer, the second insulating film being thinner than the second oxide layer, and
the step of forming the capacitor includes bringing the first conductive layer and the second conductive layer into contact with each other, and disposing the first oxide layer and the second oxide layer between the first electrode and the second electrode, by performing heat treatment after bringing the first insulating film and the second insulating film into contact with each other while the first conductive layer and the second conductive layer are disposed to face each other, and the first electrode and the second electrode are disposed to face each other.
(20) The method for manufacturing a semiconductor device according to (19), in which
the first conductive layer and the first electrode contain different metal materials from each other,
the second conductive layer and the second electrode contain different metal materials from each other, and
the step of forming the capacitor includes: performing heat treatment to bring the metal materials of the first conductive layer and the second conductive layer into contact with each other; and performing heat treatment to bring the metal materials of the first electrode and the second electrode apart from each other.

Modes of the present disclosure are not limited to the above-described respective embodiments, but include various modifications that can be conceived by those skilled in the art, and the effects of the present disclosure are not limited to the above-described effects. That is, various additions, changes, and partial deletions can be made without departing from the conceptual idea and scope of the present disclosure derived from the contents specified in the claims and equivalents and the like thereof.

REFERENCE SIGNS LIST

| | |
|---|---|
| 1 | Semiconductor device |
| 2 | Pixel chip |
| 3 | Logic chip |
| 4 | First Cu—Cu bonding region |
| 5 | Second Cu—Cu bonding region |
| 6 | First electrode |
| 7 | Oxide layer |
| 7a | First oxide layer |
| 7b | Second oxide layer |
| 8 | Second electrode |
| 9 | Insulating film |
| 9a | First insulating film |
| 9b | Second insulating film |
| 10a | First Cu layer (first conductive layer) |
| 10b | Second Cu layer (second conductive layer) |
| 11 | Resist |
| 20 | Semiconductor substrate |
| 21 | Pixel |
| 22 | Pixel array unit |
| 23 | Time code transfer unit |
| 24 | Pixel drive circuit |
| 26 | Time code generation unit |
| 27 | Vertical drive circuit |
| 28 | Output unit |
| 29 | Timing generation circuit |
| 41 | Pixel circuit |
| 51 | Comparison circuit |
| 52 | Data storage unit |
| 61 | Differential input circuit |
| 62 | Voltage conversion circuit |
| 63 | Positive feedback circuit |
| 71 | Latch control circuit |
| 72 | Latch storage unit |
| 100 | Solid-state imaging device |

What is claimed is:

1. A semiconductor device comprising:
a first substrate including a first electrode;
a second substrate including a second electrode disposed to face the first electrode; and
an oxide layer of at least one of the first electrode or the second electrode, the oxide layer being disposed between the first electrode and the second electrode.

2. The semiconductor device according to claim 1, wherein a capacitor includes the first electrode, the oxide layer, and the second electrode.

3. The semiconductor device according to claim 1, further comprising an insulating film that is disposed at least between the first electrode and the oxide layer or between the second electrode and the oxide layer, and is thinner than the oxide layer.

4. The semiconductor device according to claim 3, wherein the insulating film contains one of an oxide, a nitride, or a metal oxide.

5. The semiconductor device according to claim 2, wherein
the oxide layer includes:
a first oxide layer formed by oxidizing a surface of the first electrode; and
a second oxide layer formed by oxidizing a surface of the second electrode, and
the capacitor includes the first electrode, the first oxide layer, the second oxide layer, and the second electrode.

6. The semiconductor device according to claim 5, further comprising a first insulating film and a second insulating film that are stacked between the first oxide layer and the second oxide layer, wherein
the first insulating film and the second insulating film are thinner than the first oxide layer and the second oxide layer.

7. The semiconductor device according to claim 6, wherein the first insulating film and the second insulating film contain one of an oxide, a nitride, or a metal oxide.

8. The semiconductor device according to claim 1, further comprising:
a first conductive layer that is disposed at the same layer height as the first electrode and at a distance from the first electrode; and
a second conductive layer that is disposed at the same height as the second electrode and at a distance from the second electrode, wherein
the first conductive layer and the second conductive layer are disposed to face each other and are joined to each other.

9. The semiconductor device according to claim 8, wherein the first electrode, the second electrode, the first conductive layer, and the second conductive layer contain the same metal material.

10. The semiconductor device according to claim 8, wherein
the first electrode and the second electrode contain a first metal material, and
the first conductive layer and the second conductive layer contain a second metal material different from the first metal material.

11. The semiconductor device according to claim 10, wherein the first metal material includes a material that is less likely to cause thermal diffusion than the second metal material.

12. The semiconductor device according to claim 1, wherein the oxide layer has a thickness that is not smaller than 1 nm and not greater than 10 nm.

13. The semiconductor device according to claim 3, wherein the insulating film has a thickness that is not smaller than 0.1 nm and not greater than 1 nm.

14. The semiconductor device according to claim 6, in which each of the first insulating film and the second insulating film has a thickness that is not smaller than 0.1 nm and not greater than 1 nm.

15. The semiconductor device according to claim 2, wherein
the first substrate includes a plurality of pixels that perform photoelectric conversion,
the second substrate includes a signal processing circuit that performs signal processing on a pixel signal photoelectrically converted by the plurality of pixels, and
the pixels each include:
a photoelectric conversion element,
an analog-digital converter that compares an electric signal photoelectrically converted by the photoelectric conversion element with a reference signal, and outputs a signal indicating a comparison result, and
the capacitor.

16. The semiconductor device according to claim 15, wherein the capacitor is disposed within a region of a corresponding one of the pixels on a bonding surface between the first substrate and the second substrate.

17. A method for manufacturing a semiconductor device, the method comprising:
a step of forming a first conductive layer and a first electrode on a first substrate;
a step of forming a second conductive layer and a second electrode on a second substrate;
a step of forming an oxide layer by oxidizing a surface of at least one of the first electrode or the second electrode; and
a step of forming a capacitor including the first electrode, the oxide layer, and the second electrode by disposing the first conductive layer and the second conductive layer to face each other, bringing the first conductive layer and the second conductive layer into contact with each other, joining the first conductive layer and the second conductive layer, and disposing the first electrode and the second electrode to face each other.

18. The method for manufacturing a semiconductor device according to claim 17, further comprising a step of forming an insulating film on a surface of at least one of the first substrate or the second substrate, on which the oxide layer is formed, the insulating film being thinner than the oxide layer.

19. The method for manufacturing a semiconductor device according to claim 18, wherein
the step of forming the oxide layer includes:
a step of forming a first oxide layer by oxidizing a surface of the first electrode; and
a step of forming a second oxide layer by oxidizing a surface of the second electrode;
the step of forming the insulating film includes:
a step of forming a first insulating film on a surface of the first oxide layer, the first insulating film being thinner than the first oxide layer; and
a step of forming a second insulating film on a surface of the second oxide layer, the second insulating film being thinner than the second oxide layer, and
the step of forming the capacitor includes bringing the first conductive layer and the second conductive layer into contact with each other, and disposing the first oxide layer and the second oxide layer between the first electrode and the second electrode, by performing heat treatment after bringing the first insulating film and the second insulating film into contact with each other while the first conductive layer and the second conductive layer are disposed to face each other, and the first electrode and the second electrode are disposed to face each other.

20. The method for manufacturing a semiconductor device according to claim 19, wherein
the first conductive layer and the first electrode contain different metal materials from each other,
the second conductive layer and the second electrode contain different metal materials from each other, and
the step of forming the capacitor includes: performing heat treatment to bring the metal materials of the first conductive layer and the second conductive layer into contact with each other; and performing heat treatment to bring the metal materials of the first electrode and the second electrode apart from each other.
